(19) United States
(12) Patent Application Publication
(10) Pub. No.: US 2025/0087547 A1
(43) Pub. Date: Mar. 13, 2025

(54) ELECTRONIC DEVICE AND METHOD OF MANUFACTURING THE SAME

(71) Applicant: InnoLux Corporation, Miao-Li County (TW)

(72) Inventors: Chung-Jyh LIN, Miao-Li County (TW); Yen-Fu LIU, Miao-Li County (TW); Ju-Li WANG, Miao-Li County (TW)

(21) Appl. No.: 18/810,891

(22) Filed: Aug. 21, 2024

Related U.S. Application Data
(60) Provisional application No. 63/582,248, filed on Sep. 13, 2023.

(30) Foreign Application Priority Data
May 27, 2024 (CN) 202410660232.3

(51) Int. Cl. H01L 23/367; H01L 21/78; H01L 23/00; H01L 23/31

(52) U.S. Cl. CPC H01L 23/367; H01L 21/78; H01L 23/3107; H01L 24/24; H01L 2224/244

(57) ABSTRACT

An electronic device is provided, including a chip unit, a heat dissipation film, an encapsulation layer, a through hole, and a circuit structure. The chip unit has a first side and a second side opposite to the first side. The heat dissipation film is disposed on the first side. The encapsulation layer surrounds the chip unit and the heat dissipation film. The through hole penetrates the encapsulation layer, and has a first position and a second position. The circuit structure is disposed on the second side. The through hole is electrically connected to the chip unit through the circuit structure. The first position is connected to the circuit structure, and the second position is farther away from the circuit structure than the first position. The first position has a first width, the second position has a second width, and the first width is greater than the second width.

### CROSS REFERENCE TO RELATED APPLICATIONS

This application claims the benefit of China Application No. 202410660232.3, filed May 27, 2024, which claims the benefit of provisional Application No. 63/582,248 filed Sep. 13, 2023, the entirety of which are incorporated by reference herein.

### BACKGROUND

### Technical Field

The present disclosure is related to an electronic device, and in particular it is related to an electronic device having a packaging structure.

### Description of the Related Art

Packaging technology can increase the integration density of electronic components (e.g., transistors, diodes, resistors, capacitors, etc.) in a given area, and has been widely used in the production and manufacturing of electronic devices in recent years. As the packaging size of semiconductors becomes smaller, the reliability requirements for chip manufacturing and packaging technology are getting higher.

Electronic devices can be formed through ball grid array packaging, quad flat no-lead/dual flat no-lead packaging, and other packaging methods. For example, quad flat no-lead/dual flat no-lead packaging is a traditional wire bonding packaging technology using a lead frame. Due to its characteristics of having no pins, small size, and good heat dissipation, it has been widely used in the electronics industry. However, this type of product usually has the problem of being relatively thick.

Based on the above, developing a design for a packaging structure with better performance and reliability is still one of the current research topics in the industry.

### SUMMARY

In accordance with some embodiments of the present disclosure, an electronic device is provided. The electronic device includes a chip unit, a heat dissipation film, an encapsulation layer, a through hole, and a circuit structure. The chip unit has a first side and a second side. The second side is opposite the first side. The heat dissipation film is disposed on the first side of the chip unit. The encapsulation layer surrounds the chip unit and the heat dissipation film. The through hole penetrates the encapsulation layer. The through hole has a first position and a second position. The circuit structure is disposed on the second side of the chip unit. The through hole is electrically connected to the chip unit through the circuit structure. The first position is connected to the circuit structure, and the second position is farther away from the circuit structure than the first position. The first position has a first width, the second position has a second width, and the first width is greater than the second width.

In accordance with some embodiments of the present disclosure, a method of manufacturing an electronic device is also provided. The method includes providing a carrier substrate, providing a heat dissipation film on the carrier substrate, providing a wafer on the heat dissipation film, and performing a cutting process on the wafer to form a chip unit. The chip unit has a first side and a second side. The second side is opposite the first side. The method also includes providing an encapsulation layer surrounding the chip unit and the heat dissipation film, and forming a through hole penetrating the encapsulation layer. The through hole has a first position and a second position. The method also includes providing a circuit structure on the second side of the chip unit. The through hole is electrically connected to the chip unit through the circuit structure. Furthermore, the first position is connected to the circuit structure, and the second position is farther away from the circuit structure than the first position. The first position has a first width, the second position has a second width, and the first width is greater than the second width.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a top-view diagram of an electronic device in accordance with some embodiments of the present disclosure;

FIGS. 2A to 2E are cross-sectional diagrams of an electronic device in different stages of the manufacturing process in accordance with some embodiments of the present disclosure;

FIGS. 3A to 3D are cross-sectional diagrams of an electronic device in accordance with some embodiments of the present disclosure;

FIGS. 4A to 4E are cross-sectional diagrams of an electronic device in different stages of the manufacturing process in accordance with some embodiments of the present disclosure;

FIG. 5 is a cross-sectional diagram of an electronic device in accordance with some embodiments of the present disclosure;

FIG. 6A and FIG. 6B are cross-sectional diagrams of an electronic device in different stages of the manufacturing process in accordance with some embodiments of the present disclosure;

FIG. 7 is a cross-sectional diagram of an electronic device in accordance with some embodiments of the present disclosure;

FIGS. 8A to 8E are cross-sectional diagrams of an electronic device in different stages of the manufacturing process in accordance with some embodiments of the present disclosure;

FIG. 9A and FIG. 9B are cross-sectional diagrams of an electronic device in different stages of the manufacturing process in accordance with some embodiments of the present disclosure;

FIG. 10 is a cross-sectional diagram of an electronic device in accordance with some embodiments of the present disclosure;

FIG. 11 is a top-view diagram of an encapsulation layer of an electronic device in accordance with some embodiments of the present disclosure;

FIG. 12A and FIG. 12B are cross-sectional diagrams of an electronic device in accordance with some embodiments of the present disclosure.

### DETAILED DESCRIPTION

The electronic device and the method of manufacturing the same according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean+/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

In accordance with the embodiments of the present disclosure, a scanning electron microscope (SEM), an optical microscope (OM), a film thickness profiler (α-step), an ellipsometer or another suitable method may be used to measure the width, thickness or height of each element, or spacing or distance between elements. Specifically, in accordance with some embodiments, a scanning electron microscope may be used to obtain a cross-sectional image including the elements to be measured, and the width, thickness or height of each element, or spacing or distance between elements in the image can be measured.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, an electronic device is provided, including a packaging structure design with a heat dissipation film and a through mold via (TMV), which can reduce and thin the packaging structure and improve the heat dissipation effect, high voltage resistance and current resistance of the electronic device. Therefore, the overall performance and reliability of the electronic device can be improved.

In accordance with the embodiments of the present disclosure, the electronic device can be applied to a power module, a semiconductor packaging device, a display device, a light emitting device, a backlight device, an antenna device, a touch device, a sensing device, a wearable device, an automotive device, a battery device or a tiled device, but it is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device that senses capacitance, light, heat energy or ultrasonic waves, but it is not limited thereto. Furthermore, the electronic device may include, for example, liquid crystals, quantum dots (QDs), fluorescence, phosphorescence, other suitable materials, or a combination thereof. The electronic device may include electronic components, and the electronic components may include passive components and active components, such as capacitors, resistors, inductors, diodes, transistors, etc. The diode may include a light-emitting diode or a photodiode. The light-emitting diode may include, for example, an organic light-emitting diode (OLED), a mini light-emitting diode (mini LED), a micro-light-emitting diode (micro LED) or a quantum dot light-emitting diode (QD LED), but it is not limited thereto. In accordance with some embodiments, the electronic device may include a panel and/or a backlight module. The panel may include, for example, a liquid-crystal panel or other self-luminous panel, but it is not limited thereto. The tiled device may be, for example, a display tiled device or an antenna tiled device, but it is not limited thereto. It should be understood that the electronic device can be any permutation and combination of the above, but it is not limited thereto.

In accordance with the embodiments of the present disclosure, the method of manufacturing the electronic device provided can be applied, for example, to a wafer-level package (WLP) or panel-level package (PLP) process, and the chip first process or the chip last/RDL first process can be used, which will be explained in further detail below. In accordance with the embodiments of the present disclosure, the packaging structure of the electronic device may include a system on package (SoC), a system in package (SiP), an antenna in package (AiP), a co-packaged optics (COP), a micro electro mechanical system (MEMS) or a combination thereof, but it is not limited thereto.

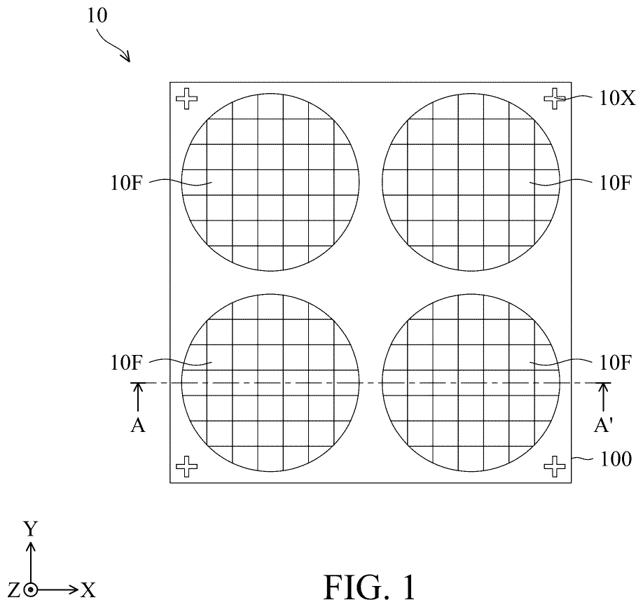

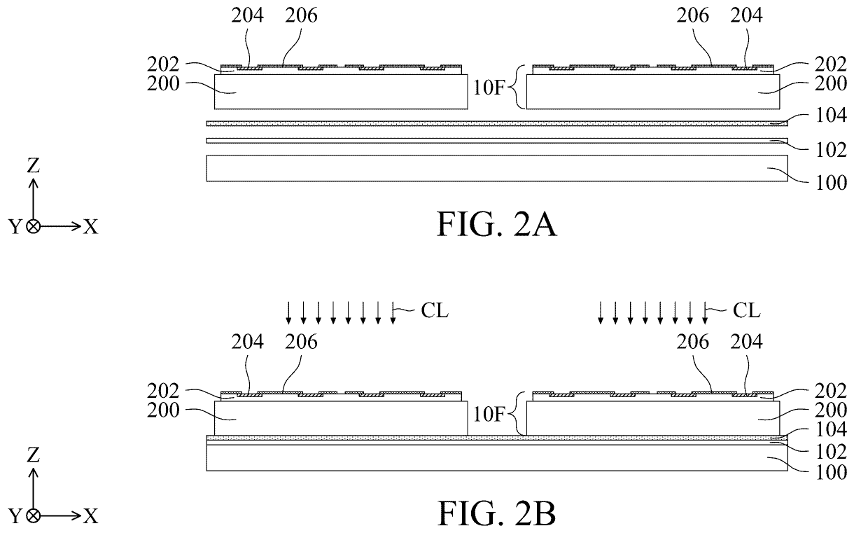

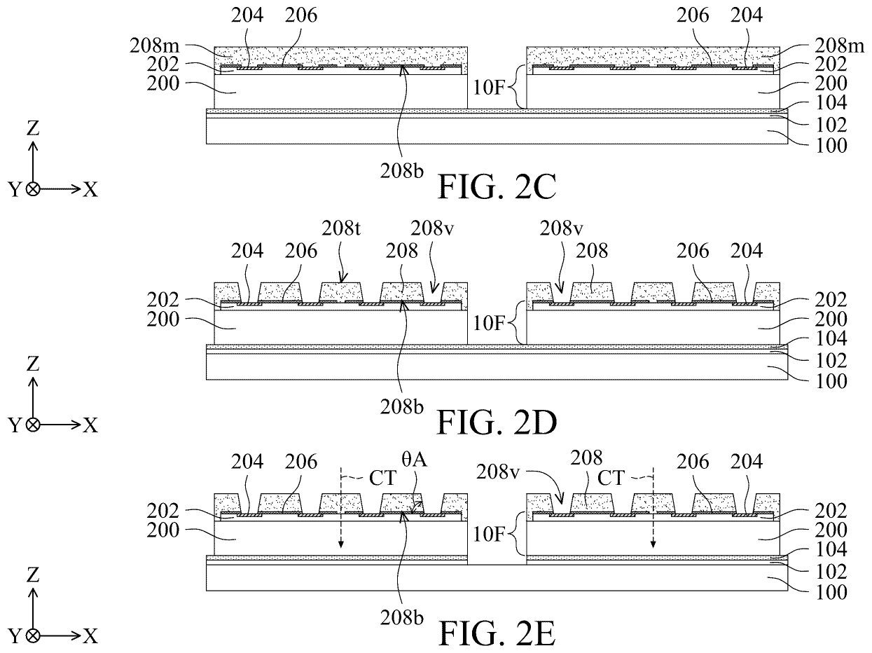

Please refer to FIG. 1 and FIGS. 2A to 2E. FIG. 1 is a top-view diagram of an electronic device 10 in accordance with some embodiments of the present disclosure. FIGS. 2A to 2E are cross-sectional diagrams of an electronic device 10 in different stages of the manufacturing process in accordance with some embodiments of the present disclosure. For clear explanation, some components of the electronic device 10 are omitted in the figure, and only some components are schematically illustrated. In accordance with some embodiments, additional features may be added to the electronic device 10 described below. In accordance with some other embodiments, some features of the electronic device 10 described below may be replaced or omitted.

FIG. 1 only shows some components of the electronic device 10 to briefly illustrate the positional relationship of the wafer units 10F in the electronic device. Specifically, FIG. 1 only shows the carrier substrate 100, the wafers 200 and the alignment marks 10X, and FIG. 1 shows the state of the electronic device 10 before being cut into chip units 10U. Furthermore, FIGS. 2A to 2E are cross-sectional diagrams of the electronic device 10 corresponding to the section line A-A′ in FIG. 1.

In addition, it should be understood that, in accordance with some embodiments, additional operating steps may be provided before, during, and/or after the method of manufacturing the electronic device 10. In accordance with some embodiments, some of the described operating steps may be replaced or omitted. In accordance with some embodiments, the order of some of the operational steps may be interchangeable.

As shown in FIG. 1, in accordance with some embodiments, the electronic device 10 includes a carrier substrate 100 and a plurality of wafer units 10F disposed on the carrier substrate 100. The wafer units 10F are disposed adjacent to each other. In accordance with some embodiments, the wafer units 10F may be arranged in an array, but it is not limited thereto. Furthermore, in accordance with some embodiments, the electronic device 10 may further include alignment marks 10X disposed on the carrier substrate 100.

The following will further describe the step flow of the method of manufacturing the electronic device 10 provided by the embodiments of the present disclosure, including the process of forming the aforementioned wafer unit 10F on the carrier substrate 100 and cutting it to form the chip unit 10U.

First, please refer to FIG. 2A, a carrier substrate 100 is provided, and a heat dissipation film 104 is formed on the carrier substrate 100. In accordance with some embodiments, before forming the heat dissipation film 104, a release layer 102 may be formed on the carrier substrate 100, so that the release layer 102 is located between the carrier substrate 100 and the heat dissipation film 104. The release layer 102 may be removed together with the carrier substrate 100 from the subsequently formed overlying structure (e.g., wafer unit 10F).

In accordance with some embodiments, the carrier substrate 100 may include a glass substrate, a ceramic substrate, a printed circuit board (PCB), a stainless steel substrate, a flame-resistant fiberglass substrate (FR4) or another suitable carrier substrate, but it is not limited thereto. In accordance with some embodiments, the carrier substrate 100 may have a recess (not shown). For example, the wafer unit 10F may be accommodated in the recess, and the adhesion flatness of subsequent film layers can be improved, thereby improving process yield or reliability of the electronic device, but it is not limited thereto.

The release layer 102 may include polymer-based materials, but it is not limited thereto. In accordance with some embodiments, the release layer 102 may include a thermal insulation material based on epoxy resin, which loses its adhesion when heated, such as thermal release tape (HRT), light-to-heat conversion (LTHC) release coating. In accordance with some other embodiments, the release layer 102 may include ultra-violet (UV) glue that loses adhesion when exposed to ultraviolet light. In accordance with still some embodiments, the release layer 102 may lose its adhesion through a laser peeling process. In accordance with some embodiments, the release layer 102 may be formed through a coating and curing process, a lamination process, another suitable process, or a combination thereof.

In accordance with some embodiments, the thermal conductivity coefficient of the heat dissipation film 104 may be between 110 W/m·K and 450 W/m·K, or between 200 W/m·K and 400 W/m·K, for example, 250 W/m·K, 300 W/m·K or 350 W/m·K, but it is not limited thereto. The heat dissipation film 104 may be a film layer containing heat dissipation material. In accordance with some embodiments, the heat dissipation film 104 may include copper, and the heat dissipation film 104 may be, for example, copper foil, but it is not limited thereto. In accordance with some embodiments, the heat dissipation film 104 may be formed on the carrier substrate 100 through a lamination process, a coating process, a chemical vapor deposition process, a physical vapor deposition process, an electroplating process, an electroless plating process, another suitable method, or a combination thereof.

Please continue to refer to FIG. 2A. The wafer unit 10F then is formed on the heat dissipation film 104. In accordance with some embodiments, wafer unit 10F may include a wafer 200, an interposer 202, conductive pads 204, and a passivation layer 206. In accordance with some embodiments, the wafer 200 may include, for example, a known-good wafer (KGW), but it is not limited thereto. The wafer material may include silicon, silicon carbide, gallium nitride, gallium arsenide or another suitable wafer material, but it is not limited thereto. The wafer materials can be used to form semiconductor structures such as MOSFETs or BJTs through process steps such as lithography, doping, and chemical mechanical polishing (CMP). The wafer unit 10F may include the interposer 202 and conductive pads 204 disposed on the wafer 200. The interposer 202 may have a single-layer or multi-layer structure, and the conductive pads 204 may be electrically connected to the wafer 200. The interposer 202 and the conductive pads 204 may be formed through thin film deposition, CMP, chemical plating or electroplating steps. Through the above steps, the wafer unit 10F is further formed. In other words, the wafer unit 10F may be, for example, an integrated circuit, but it is not limited thereto.

In accordance with some embodiments, the interposer 202 may include an inorganic insulating material. The inorganic insulating material may include, for example, silicon nitride, silicon oxide, silicon oxynitride, another suitable material, or a combination thereof, but it is not limited thereto. In accordance with some embodiments, the interposer 202 may be formed by a coating process, a spin coating process, a chemical vapor deposition process, another suitable method, or a combination thereof. Furthermore, a portion of the interposer 202 may be removed through one or more photolithography processes and/or etching processes, for example, to form a plurality of openings (not labeled) on the top of the interposer 202. In accordance with some embodiments, the photolithography process may include photoresist coating (e.g., spin coating), soft baking, hard baking, mask alignment, exposure, post-exposure baking, photoresist development, cleaning and drying, etc., but it is not limited thereto. The etching process may include a dry etching process or a wet etching process, but it is not limited thereto.

In accordance with some embodiments, the material of the conductive pad 204 may include copper (Cu), titanium (Ti), aluminum (Al), tungsten (W), silver (Ag), gold (Au), tin (Sn), molybdenum (Mo), chromium (Cr), nickel (Ni), platinum (Pt), alloys of the aforementioned metals, another suitable conductive material, or a combination thereof, but it is not limited thereto. In accordance with some embodiments, the conductive pad 204 may be formed by a physical vapor deposition process, an electroplating process, an electroless plating process, another suitable method, or a combination thereof. Specifically, the conductive pads 204 may fill a plurality of openings located on top of interposer 202. In accordance with some embodiments, a planarization process may then be performed to make the top surface of the interposer 202 and the top surface of the conductive pad 204 substantially aligned or coplanar. In accordance with some embodiments, the planarization process may include a grinding process, a chemical-mechanical polish (CMP) process, another suitable planarization process, or a combination thereof.

Next, a passivation layer 206 is formed on the interposer 202 and the conductive pads 204. In accordance with some embodiments, the passivation layer 206 may partially cover the conductive pad 204 and expose a portion of the conductive pad 204, for example, expose a portion of the top surface of the conductive pad 204. In other words, in accordance with some embodiments, the passivation layer 206 may partially overlap the conductive pad 204 in the normal direction of the carrier substrate 100 (e.g., the Z direction in the figure).

In accordance with some embodiments, the material of the passivation layer 206 may include an inorganic material, an organic material, or a combination thereof, but it is not limited thereto. For example, the inorganic material may include silicon nitride, silicon oxide, silicon oxynitride, another suitable material, or a combination thereof, but it is not limited thereto. For example, the organic material may include polyethylene terephthalate (PET), polyethylene (PE), polyethersulfone (PES), polycarbonate (PC), polymethylmethacrylate (PMMA), polyimide (PI), photosensitive polyimide (PSPI), another suitable passivation material or a combination thereof, but it is not limited thereto. In accordance with some embodiments, the passivation layer 206 may be formed by a coating process, a spin coating process, a chemical vapor deposition process, another suitable method, or a combination thereof. Furthermore, a portion of the passivation layer 206 may be removed through one or more photolithography processes and/or etching processes to expose a portion of the top surface of the conductive pad 204. In accordance with some embodiments, the passivation layer 206 may include a single layer or a stack of multiple film layers. The materials of the film layers may be the same or different. The thermal expansion coefficient of one layer of the passivation layer 206 may be between 0.1 ppm/° C. to 10 ppm/° C.

Referring to FIG. 2B, in accordance with some embodiments, a surface treatment CL is then performed on the top surface of the wafer unit 10F, such as the top surfaces of the exposed conductive pads 204 and the passivation layer 206. In accordance with some embodiments, the surface treatment CL may include a surface cleaning process, such as a plasma surface cleaning process, but it is not limited thereto. In accordance with some embodiments, the step of surface treatment CL may be omitted.

Referring to FIG. 2C, a buffer material 208m is then formed on the wafer unit 10F. Specifically, the buffer material 208m may be formed on the wafer 200, the conductive pads 204 and the passivation layer 206, and cover the top surfaces of the conductive pads 204 and the passivation layer 206 and part of the top surface of the wafer 200.

In accordance with some embodiments, the thermal expansion coefficient (CTE) of the buffer material 208m may be between 10 ppm/° C. and 50 ppm/° C. (i.e. 10 ppm/° C.≤the thermal expansion coefficient of the buffer material 208m≤50 ppm/° C.), and the thermal expansion coefficient of the buffer material 208m may be greater than the thermal expansion coefficient of the passivation layer 206. In accordance with some embodiments, the Young's module of the buffer material 208m may be between 3 GPa and 15 GPa (3 GPa≤Young's module of the buffer material 208m≤15 GPa). In accordance with some embodiments, the elastic coefficient of the buffer material 208m may be between 50 MPa and 110 MPa (50 MPa≤the elastic coefficient of the buffer material 208m≤110 MPa). In accordance with some embodiments, the buffer material 208m may include a polymer insulating material, such as ABF build-up film (Ajinomoto Build-up Film), polybenzobis-oxazole (PBO), polyimide, photosensitive polyimide (PSPI), phenylcyclobutene (BCB), epoxy resin, another suitable buffer material or a combination thereof, but it is not limited thereto. Furthermore, in accordance with some embodiments, the buffer material 208m may further include fillers, and the particle size of the fillers may be between 0.05 μm and 10 μm, or the maximum particle size of the fillers may be between 0.05 μm and 10 m. In accordance with some embodiments, the buffer material 208m may be formed by a coating process, a spin coating process, a chemical vapor deposition process, a lamination process, or another suitable method or a combination thereof.

Referring to FIG. 2D, a patterning process is performed on the buffer material 208m to form the buffer layer 208. In detail, a portion of the buffer material 208m may be removed to form an opening 208v, and the opening 208v may expose a portion of the top surface of the conductive pad 204. As shown in FIG. 2D, in accordance with some embodiments, the patterned buffer layer 208 has a first surface 208t (e.g., the top surface of the buffer layer 208 in FIG. 2D) and a second surface 208b (e.g., the bottom surface of the buffer layer 208 in FIG. 2D) opposite to the first surface 208, the first surface 208t is farther from the wafer 200 than the second surface 208b, and the width of the first surface 208t may be different from the width of the second surface 208b, for example, the width of the first surface 208t may be smaller than the width of the second surface 208b. In other words, the opening 208v may have an inclined side wall, wherein the angle θA between the side wall and the second surface 208b may be between 55 degrees and 85 degrees (55 degrees≤the angle θA≤85 degrees). Through the above design, the structural stability between the buffer layer 208 and other film layers can be improved.

In accordance with some embodiments, a portion of the buffer material 208m may be removed through one or more photolithography processes and/or etching processes to form the buffer layer 208. In accordance with some other embodiments, a portion of the buffer material 208m may be removed through a laser process to form the buffer layer 208.

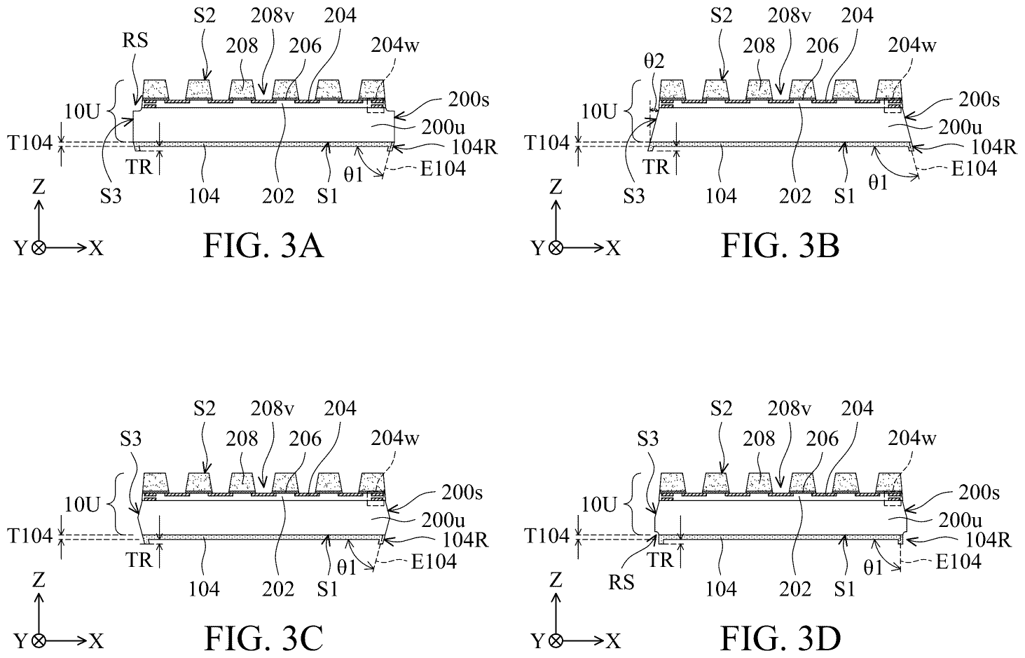

Referring to FIG. 2E, after the buffer layer 208 is formed, a cutting process CT is performed on the wafer unit 10F. Specifically, the cutting process CT may be performed on the wafer 200, the interposer 202 and the buffer layer 208 to form the chip unit 10U (the structure of the chip unit 10U will be described in detail in FIGS. 3A to 3D). In accordance with some embodiments, the cutting process CT may also cut the release layer 102 and the heat dissipation film 104 together. In accordance with some embodiments, cutting may be performed along dicing lanes (not illustrated) passing through the buffer layer 208 and the wafer 200 to form the chip unit 10U. The dicing lanes may be substantially perpendicular to the normal direction of the carrier substrate 100 (e.g., the Z direction in the figures) (referring to the line segment drawn on the wafer unit 10F in FIG. 1). In accordance with some embodiments, the cutting process CT may include a laser cutting process, a knife cutting process, or a combination thereof, but it is not limited thereto. Through the design of the buffer layer 208 mentioned above, risks such as chip breakage during the cutting process can be reduced, but it is not limited thereto.

Please refer to FIGS. 3A to 3D, which are cross-sectional diagrams of an electronic device in accordance with some embodiments of the present disclosure. Specifically, FIGS. 3A to 3D show partial cross-sectional diagrams of the electronic device obtained by following the steps shown in FIG. 2E. Further, FIGS. 3A to 3D show the partial structure of the electronic device obtained after performing the cutting process CT on the wafer unit 10F and removing the release layer 102 and the carrier substrate 100 (for clarity of explanation, only the corresponding area of a single chip is shown). In accordance with some embodiments, the release layer 102 may lose its adhesion through a laser peeling process, so that the heat dissipation film 104 and the chip unit 10U are separated from the release layer 102 and the carrier substrate 100.

As shown in FIGS. 3A to 3D, the chip unit 10U may include a chip 200u and an interposer 202, a conductive pad 204, a passivation layer 206 and a buffer layer 208 disposed on the chip 200u. The chip unit 10U may have a first side S1, a second side S2 opposite to the first side S1, and a third side S3 connecting the first side S1 and the second side S2. The first side S1 may be the side close to the chip 200u., the second side S2 may be the side close to the buffer layer 208, and the third side S3 may connect the first side S1 and the second side S2. In accordance with some embodiments, the angle between the third side S3 and the normal direction may be greater than or equal to 1 degree and less than or equal to 10 degrees. Furthermore, the heat dissipation film 104 may be disposed on the first side S1 of the chip unit 10U.

In accordance with some embodiments, the heat dissipation film 104 may have a protruding portion 104R that protrudes in a direction away from the chip 200u. In accordance with some embodiments, an included angle θ1 between the extending direction E104 of the protruding portion 104R and the first side S1 of the chip unit 10U may be between 45 degrees and 135 degrees. For example, the included angle θ1 may be 50 degrees, 55 degrees, 60 degrees, 65 degrees, 70 degrees, 75 degrees, 80 degrees, 85 degrees, 90 degrees, 95 degrees, 100 degrees, 105 degrees, 110 degrees, 115 degrees, 120 degrees, 125 degrees or 130 degrees, but it is not limited thereto.

In accordance with some embodiments, the heat dissipation film 104 may have a first thickness T104, the protruding portion 104R may have a second thickness TR, and the first thickness T104 and the second thickness TR conform to the following relationship: 1.2×the first thickness T104≤the second thickness TR≤5× the first thickness T104. That is, the second thickness TR of the protruding portion 104R is greater than or equal to 1.2 times the first thickness T104 of the heat dissipation film 104, and the second thickness TR of the protruding portion 104R is less than or equal to 5 times the first thickness T104 of the heat dissipation film 104. In accordance with some embodiments, the second thickness TR may be, for example, 1.5 times, 1.6 times, 1.7 times, 1.8 times, 1.9 times, 2 times, 2.1 times, 2.2 times, 2.3 times, 2.4 times, 2.5 times, 3 times, 3.5 times, 4 times, 4.5 times or 4.9 times the first thickness T104, but it is not limited thereto.

In accordance with the embodiments of the present disclosure, the aforementioned first thickness T104 refers to the thickness of the heat dissipation film 104 other than the protruding portion 104R in the normal direction (for example, the Z direction in the figure) of the bottom surface (not labeled, the surface of the chip 200u adjacent to the heat dissipation film 104 in FIG. 3A) of the chip 200u; the aforementioned second thickness TR refers to the thickness of the protruding portion 104R of the heat dissipation film 104 in the normal direction of the bottom surface (not labeled, the surface of the chip 200u adjacent to the heat dissipation film 104 in FIG. 3A) of the chip 200u.

It should be noted that the heat dissipation film 104 with the aforementioned protruding portion 104R configuration can increase the bonding area with the subsequent formed material of the encapsulation layer 300, increase the structural adhesion between components, or further improve the heat dissipation performance.

In addition, in accordance with some embodiments, the chip unit 10U further includes a wall structure 204w, which may be disposed between the chip 200u and the buffer layer 208 and adjacent to the side surface 200s of the chip 200u. In accordance with some embodiments, the wall structure 204w also may be disposed in the interposer 202, and the wall structure 204w may be disposed between the conductive pad 204 and the chip 200u. The material and method of manufacturing the wall structure 204w may be the same as or similar to those of the aforementioned conductive pad 204, and will not be repeated here. The wall structure 204w can absorb or relieve the stress generated by the cutting process CT. The wall structure 204w may include two metal layers that at least partially overlap each other.

In accordance with some embodiments, the cutting process CT includes a laser cutting process performed from the second side S2 of the chip unit 10U, and subsequently a knife cutting process performed from the second side S2 of the chip unit 10U. Specifically, the laser cutting process may first at least partially cut the chip 200u, and then the knife cutting process is performed. As shown in FIG. 3A, in this embodiment, the top portion (not labeled) of the chip 200u may have at least one recess RS, and the top portion of the chip 200u may be the side close to the buffer layer 208. The recess RS may be adjacent an edge of chip 200u. In this embodiment, the side surface 200s of the chip 200u may have a profile that is substantially perpendicular to the bottom surface (not labeled) of the chip 200u. Furthermore, in this embodiment, the included angle θ1 between the extending direction E104 of the protruding portion 104R and the first side S1 of the chip unit 10U may be between 45 degrees and 90 degrees.

In accordance with some embodiments, the cutting process CT may include a knife cutting process from the second side S2 of the chip unit 10U. As shown in FIG. 3B, in this embodiment, the side surface 200s of the chip 200u may have at least one inclined profile. For example, in the direction from the second side S2 to the first side S1 of the chip unit 10U, the side surface 200s may be outwardly inclined, but it is not limited thereto. Furthermore, the inclined profile can be regarded as the third side S3, which connects the first side S1 and the second side S2. An angle θ2 between the third side S3 and the normal direction of the bottom surface of the chip 200u may be greater than or equal to 1 degree, and less than or equal to 10 degrees. Furthermore, in this embodiment, the included angle θ1 between the extending direction E104 of the protruding portion 104R and the first side S1 of the chip unit 10U may be between 105 degrees and 135 degrees.

In accordance with some embodiments, the cutting process CT may include a knife cutting process performed from the second side S2 of the chip unit 10U, and a knife cutting process performed from the first side S1 of the chip unit 10U. As shown in FIG. 3C, in this embodiment, the side surface 200s of the chip 200u may have at least one inclined profile. For example, in the direction from the second side S2 to the first side S1 of the chip unit 10U, the side surface 200s may be first outwardly inclined and then inwardly inclined, but it is not limited thereto. Furthermore, in this embodiment, the included angle θ1 between the extending direction E104 of the protruding portion 104R and the first side S1 of the chip unit 10U may be substantially 90 degrees.

In accordance with some embodiments, the cutting process CT may include a laser cutting process performed from the first side S1 of the chip unit 10U, and subsequently a knife cutting process performed from the second side S2 of the chip unit 10U. Specifically, the laser cutting process may first at least partially cut the chip 200u, and then the knife cutting process is performed. As shown in FIG. 3D, in this embodiment, the bottom portion (not labeled) of the chip 200u may have a recess RS, and the bottom portion of the chip 200u may be the side close to the heat dissipation film 104. The recess RS may be adjacent an edge of chip 200u. In this embodiment, the side surface 200s of the chip 200u may have at least one inclined profile. For example, in the direction from the second side S2 to the first side S1 of the chip unit 10U, the side surface 200s may first be outwardly inclined and then substantially perpendicular to the bottom surface (not labeled) of the chip 200u, but it is not limited thereto. Furthermore, in this embodiment, the included angle θ1 between the extending direction E104 of the protruding portion 104R and the first side S1 of the chip unit 10U may be substantially 55 degrees.

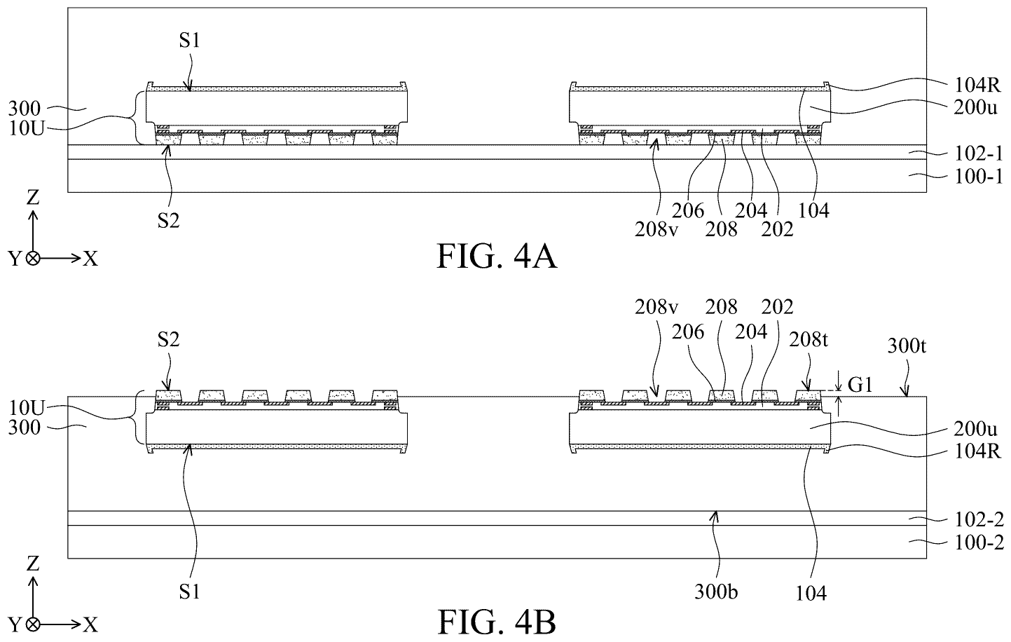

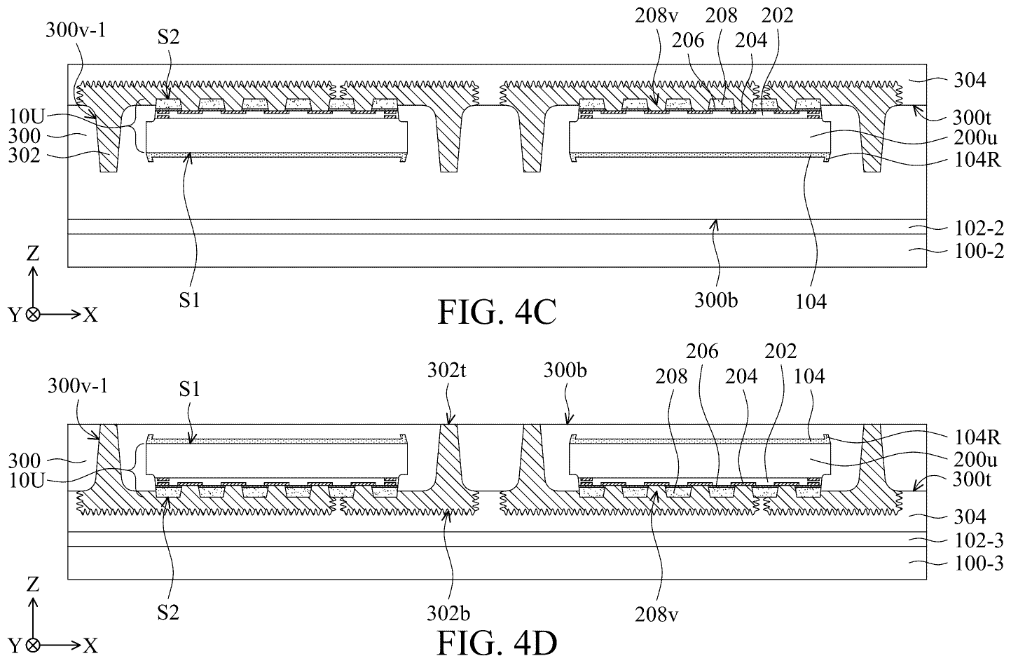

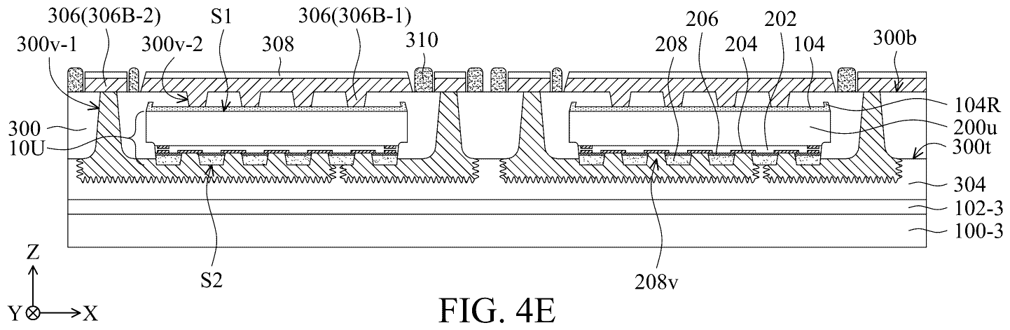

Please refer to FIGS. 4A to 4E, which are cross-sectional diagrams of an electronic device in different stages of the manufacturing process in accordance with some embodiments of the present disclosure. Specifically, FIGS. 4A to 4E show partial cross-sectional diagrams of an electronic device obtained by continuing the packaging process with the structure shown in FIG. 3A.

It should be understood that, in accordance with some embodiments, additional operating steps may be provided before, during and/or after the following manufacturing method. In accordance with some embodiments, some of the described operating steps may be replaced or omitted. In accordance with some embodiments, the order of some of the operational steps may be interchangeable. In addition, it should be understood that components or elements that are the same as or similar to those mentioned above will be denoted by the same or similar numerals, and their materials and functions are the same or similar to those described above, and thus will not be repeated in the following description.

First, please refer to FIG. 4A. The structure including the chip unit 10U and the heat dissipation film 104 shown in FIG. 3A may be disposed on the first carrier substrate 100-1. For example, the steps of disposing the chip unit 10U and the heat dissipation film 104 may include pick and place, but it is not limited thereto. In addition, the manner of disposing the chip unit 10U may include arranging the first side S1 toward the first carrier substrate 100-1 (i.e. chip-face-down) or arranging the second side S2 toward the first carrier substrate 100-1 (i.e. chip-face-up). Moreover, the first release layer 102-1 may be formed on the first carrier substrate 100-1 first, so that the first release layer 102-1 is located between the first carrier substrate 100-1 and the chip unit 10U. The first release layer 102-1 may be removed together with the first carrier substrate 100-1 from the subsequently formed overlying structure. The materials and methods of manufacturing the first carrier substrate 100-1 and the first release layer 102-1 may be the same or similar to those of the aforementioned carrier substrate 100 and the release layer 102, and will not be repeated here.

Next, continuing to refer to FIG. 4A, an encapsulation layer 300 is formed to surround the chip unit 10U and the heat dissipation film 104. In accordance with some embodiments, the encapsulation layer 300 may be formed over the first carrier substrate 100-1 and the first release layer 102-1, and cover the chip unit 10U and the heat dissipation film 104. The encapsulation layer 300 can reduce the influence of water and oxygen in the external environment on the chip unit 10U or can alleviate warpage during the manufacturing process, but it is not limited thereto. The encapsulation layer 300 may be in contact with the surface of the chip unit 10U and the heat dissipation film 104.

In accordance with some embodiments, the encapsulation layer 300 may include molding compound, epoxy, another suitable encapsulating material, or a combination thereof, but it is not limited thereto. In accordance with some embodiments, the encapsulation layer 300 may be formed by a compression molding process, a transfer molding process, or another suitable method. In accordance with some embodiments, the encapsulation layer 300 may be in a film, powder, liquid or semi-liquid form for a molding process and then solidified, but it is not limited thereto.

Please continue to refer to FIG. 4B. The first carrier substrate 100-1 and the first release layer 102-1 then are removed, and the structures of the aforementioned chip unit 10U, the heat dissipation film 104 and the encapsulation layer 300 are inverted and placed on a second carrier substrate 100-2. In detail, in accordance with some embodiments, the first release layer 102-1 may lose its adhesion through a laser peeling process, so that the chip unit 10U, the heat dissipation film 104 and the encapsulation layer 300 are separated from the first release layer 102-1 and the first carrier substrate 100-1. Moreover, the second release layer 102-2 may be formed on the second carrier substrate 100-2 first, so that the second release layer 102-2 is located between the second carrier substrate 100-2 and the encapsulation layer 300. The second release layer 102-2 may be removed together with the second carrier substrate 100-2 from the subsequently formed overlying structure. In accordance with some embodiments, the inverting step may be omitted.

As shown in FIG. 4B, after being inverted, the buffer layer 208 of the chip unit 10U may be disposed above, and the opening 208v may expose a portion of the conductive pad 204. The encapsulation layer 300 may have a first surface 300t (e.g., the top surface of the encapsulation layer 300 in FIG. 4B) and a second surface 300b (e.g., the bottom surface of the encapsulation layer 300 in FIG. 4B) opposite to the first surface 300t. The first surface 300t is closer to the buffer layer 208 than the second surface 300b. In accordance with some embodiments, the first surface 208t of the buffer layer 208 is not aligned with the first surface 300t of the encapsulation layer 300, and the first surface 208t of the buffer layer 208 is higher than the first surface 300t of the encapsulation layer 300. In accordance with some embodiments, there may be a gap G1 between the first surface 208t of the buffer layer 208 and the first surface 300t of the encapsulation layer 300, and the gap G1 may be between 0.5 micrometers (μm) and 10 μm (i.e. 0.5 μm≤the gap G1≤10 μm), or between 1 μm and 5 μm, such as 1.5 μm, 2 μm, 2.5 μm, 3 μm, 3.5 μm, 4 μm or 4.5 μm, but it is not limited thereto.

In accordance with the embodiments of the present disclosure, the aforementioned gap G1 refers to the distance between the first surface 208t of the buffer layer 208 and the first surface 300t of the encapsulation layer 300 in the normal direction of the second carrier substrate 100-2 (for example, the Z direction in the figure).

It should be noted that when the distance G1 between the first surface 208t of the buffer layer 208 and the first surface 300t of the encapsulation layer 300 is within the aforementioned range, the buffer layer 208 can provide sufficient buffering stress during the subsequent packaging process and improve the stability of the structure.

Referring to FIG. 4C, a through hole 300v-1 then is formed in the encapsulation layer 300, and a conductive layer 302 is formed in the through hole 300v-1. Specifically, a patterning process may be performed to remove a portion of the encapsulation layer 300 from the first surface 300t of the encapsulation layer 300 to form the through hole 300v-1. In accordance with some embodiments, the position of the bottom surface of the through hole 300v-1 may be lower than the position of the protruding portion 104R of the heat dissipation film 104. In addition, the conductive layer 302 may also be formed on the encapsulation layer 300 and the buffer layer 208 and fill the opening 208v of the buffer layer 208. The conductive layer 302 may be electrically connected to the chip unit 10U through the opening 208v.

In accordance with some embodiments, a portion of the encapsulation layer 300 may be removed through one or more photolithography processes and/or etching processes to form the through hole 300v-1 in the encapsulation layer 300. Furthermore, the conductive layer 302 includes conductive material. In accordance with some embodiments, the conductive layer 302 may include copper (Cu), titanium (Ti), aluminum (Al), tungsten (W), silver (Ag), gold (Au), tin (Sn), molybdenum (Mo), chromium (Cr), nickel (Ni), platinum (Pt), tantalum (Ta), alloys of the aforementioned metals, another suitable conductive material, or a combination thereof, but it is not limited thereto. In accordance with some embodiments, the conductive layer 302 may have a multi-layer structure (not shown). In accordance with some embodiments, the conductive material may be formed by an atomic layer deposition process, a physical vapor deposition process, an electroplating process, an electroless plating process, another suitable method, or a combination thereof. Furthermore, the conductive material may be patterned through one or more photolithography processes and/or etching processes to form the conductive layer 302. In accordance with some embodiments, before forming the circuit structure 304, the surface of the buffer layer 208 or the encapsulation layer 300 may be selectively roughened. Through the above steps, the bonding strength between the circuit structure 304 and the buffer layer 208 or the encapsulation layer 300 can be improved, but it is not limited thereto.

Continuing to refer to FIG. 4C, a circuit structure 304 then is formed on the second side S2 of the chip unit 10U, and the through hole 300v-1 is electrically connected to the chip unit 10U through the circuit structure 304. The circuit structure 304 may be formed over conductive layer 302. Furthermore, in accordance with some embodiments, the circuit structure 304 may be electrically connected to the chip 200u through the opening 208v of the buffer layer 208.

In accordance with some embodiments, the circuit structure 304 may be a redistribution layer (RDL), which can include at least one conductive layer (not shown) and at least one insulating layer (not shown). The circuit structure 304 can redistribute circuits of the electronic device and/or further increase the circuit fan-out area, or different electronic components can be electrically connected to each other through the circuit structure 304. For example, the distance between two adjacent contact pads of the circuit structure 304 at the end close to the chip 200u may be less than or equal to the distance between two adjacent contact pads in the circuit structure 304 at the end far away from the chip 200u. Therefore, the circuit structure 304 can adjust the circuit fanout conditions, but it is not limited thereto. Furthermore, the circuit structure 304 can be applied to wafer level chip scale package (WLCSP), wafer level package (WLP), panel level package (PLP) or another packaging method, but it is not limited thereto.

In accordance with some embodiments, the material and manufacturing method of the conductive layer of the circuit structure 304 may be the same or similar to those of the aforementioned conductive layer 302, and will not be repeated here. In accordance with some embodiments, the material of the insulating layer of the circuit structure 304 may include a polymer dielectric insulating material, such as polybenzoxazole (PBO), polyimide, or benzocyclobutene (BCB), another suitable polymeric dielectric material, or a combination thereof, but it is not limited thereto. In accordance with some other embodiments, the material of the insulating layer of the circuit structure 304 may include silicon nitride, silicon oxide, silicon oxynitride, phosphosilicate glass (PSG), borosilicate glass (BSG), boron-doped phosphosilicate glass (BPSG), another suitable dielectric material, or a combination thereof, but it is not limited thereto. In accordance with some embodiments, the insulating layer may be formed by a coating process, a spin coating process, a chemical vapor deposition process, a stacking process, another suitable method, or a combination thereof. In addition, in accordance with some embodiments, a surface treatment may be performed on the conductive layer and the insulating layer of the circuit structure 304. The surface treatment may include, for example, roughening the surface of the conductive layer or the surface of the insulating layer so that the conductive layer or the insulating layer has a rough surface to improve the bonding ability between film layers.

In accordance with the embodiments of the present disclosure, the roughened surface refers to a distance difference between the peaks and valleys of the surface undulations is in a range from 0.15 μm to 3 μm when observed with an electron microscope. The roughness can be determined by using a scanning electron microscope (SEM) or a transmission electron microscope (TEM) to observe the surface undulations at appropriate magnification. The surface undulations conditions per unit length (for example, 10 μm) are compared. Here, “appropriate magnification” means that at least 10 undulating peaks and valleys can be observed on at least one surface under this magnification.

Referring to FIG. 4D, the second carrier substrate 100-2 and the second release layer 102-2 then are removed, and the structure originally disposed on the second carrier substrate 100-2 can be inverted and disposed on a third carrier substrate 100-3. In detail, in accordance with some embodiments, the second release layer 102-2 may lose its adhesion through a laser peeling process, so that the structures originally disposed on the second carrier substrate 100-2 are separated from the second release layer 102-2 and the second carrier substrate 100-2. Moreover, the third release layer 102-3 may be formed on the third carrier substrate 100-3 first, so that the third release layer 102-3 is located between the third carrier substrate 100-3 and the circuit structure 304. The third release layer 102-3 may be removed together with the third carrier substrate 100-3 from the subsequently formed overlying structure.

As shown in FIG. 4D, after being inverted, the chip unit 10U is disposed above and the circuit structure 304 is disposed below. Then, a planarization process may be performed on the second surface 300b of the encapsulation layer 300 to expose the through hole 300v-1. The through hole 300v-1 (or the conductive layer 302 disposed therein) may have a first surface 302t (e.g., the top surface of conductive layer 302 in FIG. 4D) and a second surface 302b (e.g., the bottom surface of the conductive layer 302 in FIG. 4D) opposite first surface 302t, and the first surface 302t is farther away from the circuit structure 304 than the second surface 302b. In accordance with some embodiments, the planarization process may be optionally performed so that the second surface 300b of the encapsulation layer 300 and the first surface 302t of the conductive layer 302 disposed in the through hole 300v-1 are substantially aligned or coplanar. In accordance with some embodiments, the planarization process may include a grinding process, a chemical-mechanical polish (CMP) process, another suitable planarization process, or a combination thereof. In accordance with some embodiments, the step of planarization process may be omitted.

Referring to FIG. 4E, an insulating layer 310 then is formed on the encapsulation layer 300. The insulating layer 310 can be used to define the positions where the opening 300v-2 and the conductive layer 306 are subsequently formed. For example, the portion of the encapsulation layer 300 that is not covered by the insulating layer 310 may serve as the position for electrical connection with the subsequently formed conductive layer 306.

In accordance with some embodiments, the insulating layer 310 may be formed of a solder resist material. In accordance with some embodiments, the insulating layer 310 includes an insulating material, such as solder mask, epoxy resin, an inorganic material (for example, silicon oxide, silicon nitride, silicon oxynitride, metal oxide or a combination thereof), an organic polymer material (for example, polyimide resin, phenylcyclobutene, parylene, naphthalene polymer, fluorocarbon, or acrylate), another suitable insulating material or a combination thereof, but it is not limited thereto. In accordance with some embodiments, the insulating layer 310 may be formed by a coating process, a spin coating process, a chemical vapor deposition process, another suitable method, or a combination thereof.

Next, an openings 300v-2 is formed in the encapsulation layer 300, and a conductive layer 306 is formed in the opening 300v-2. Specifically, a patterning process may be performed to remove a portion of the encapsulation layer 300 from the second surface 300b of the encapsulation layer 300 to form the opening 300v-2. The opening 300v-2 may extend from the second surface 300b of the encapsulation layer 300 to the surface of the heat dissipation film 104, and the opening 300v-2 may expose a portion of the heat dissipation film 104. In addition, the conductive layer 306 also may be formed on the encapsulation layer 300 and in contact with the conductive layer 302 disposed in the through hole 300v-1, so that the conductive layer 306 is electrically connected to the conductive layer 302, and then is electrically connected to the chip unit 10U. In accordance with some embodiments, the portion of the conductive layer 306 disposed on the second surface 300b of the encapsulation layer 300 and substantially corresponding to or overlapping the chip unit 10U may serve as a conductive bump (labeled as 306B-1 for convenience of explanation). The conductive bump 306B-1 may be connected to the heat dissipation film 104 through the opening 300v-2 of the encapsulation layer 300. In some embodiments, the conductive bump 306B-1 may be electrically connected to the heat dissipation film 104 through the opening 300v-2 of the encapsulation layer 300. In accordance with some embodiments, the conductive layer 306 disposed on the second surface 300b of the encapsulation layer 300 and substantially corresponding to or overlapping the through hole 300v-1 may serve as a conductive bump (labeled as 306B-2 for convenience of explanation). The conductive bump 306B-2 may be in contact with the through hole 300v-1.

In accordance with some embodiments, a portion of the encapsulation layer 300 may be removed through one or more photolithography processes (for example, using the insulating layer 310 as a mask) and/or etching processes to form the opening 300v-2 in the encapsulation layer 300. Furthermore, the material and method of manufacturing the conductive layer 306 may be the same or similar to those of the conductive layer 302 described above, and will not be repeated here.

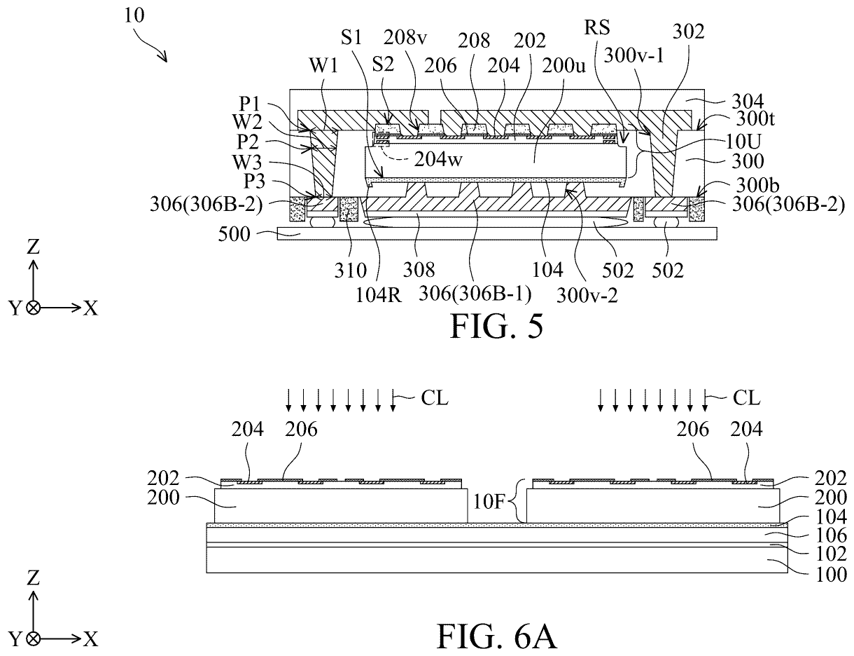

Continuing to refer to FIG. 4E, a bonding element 308 then is formed on the conductive layer 306. The bonding element 308 may be bonded to subsequently formed connection pad 502 (e.g., as shown in FIG. 5), and may be electrically connected to external electronic components through the connection pad 502.

In accordance with some embodiments, the material of the bonding element 308 may include tin, silver, lead-free tin, copper, nickel, gold, gallium, another suitable material, or a combination thereof, but it is not limited thereto. In accordance with some embodiments, the bonding element 308 may be formed by a physical vapor deposition process, an electroplating process, an electroless plating process, another suitable method, or a combination thereof.

Please refer to FIG. 5, which is a cross-sectional diagram of the electronic device 10 in accordance with some embodiments of the present disclosure. Specifically, FIG. 5 shows a partial cross-sectional diagram of a structure obtained by further bonding the electronic device shown in FIG. 4E to an external electronic component 500.

As shown in FIG. 5, in accordance with some embodiments, the aforementioned third carrier substrate 100-3 and the third release layer 102-3 are removed, and the structures originally disposed on the third carrier substrate 100-3 are inverted and bonded to the external electronic components 500. In detail, in accordance with some embodiments, the third release layer 102-3 may lose its adhesion through a laser peeling process, so that the structures originally disposed on the third carrier substrate 100-3 are separated from the third release layer 102-3 and the third carrier substrate 100-3.

Referring to FIG. 5, the electronic device 10 formed by the aforementioned manufacturing method includes a chip unit 10U, a heat dissipation film 104, an encapsulation layer 300, a through hole 300v-1 and a circuit structure 304. The chip unit 10U has a first side S1 and a second side S2 opposite the first side S1. Furthermore, the heat dissipation film 104 may be disposed on the first side S1 of the chip unit 10U. The encapsulation layer 300 may surround the chip unit 10U and the heat dissipation film 104. The through hole 300v-1 may penetrate the encapsulation layer 300, for example, may extend from the first surface 300t to the second surface 300b of the encapsulation layer 300. The circuit structure 304 may be disposed on the second side S2 of the chip unit 10U, and the through hole 300v-1 may be electrically connected to the chip unit 10U through the circuit structure 304. In accordance with some embodiments, the electronic device 10 may include a plurality of chip units, the plurality of chip units may have the same or different functions, the plurality of chip units may be arranged in one direction or stacked on each other, and the plurality of chip units may be surrounded by the encapsulation layer 300. In accordance with some embodiments, the electronic device 10 may further include other electronic components adjacent to the chip unit. The electronic components may be, for example, resistors, capacitors, inductors, or other suitable electronic components. The chip unit and the electronic components are surrounded by the encapsulation layer 300 to form an electronic device or a packaging device. The term “surround” used herein means that in a cross-sectional view, at least part of the component A is disposed between two adjacent components B.

Moreover, the through hole 300v-1 has a first position P1 and a second position P2. The first position P1 is connected to the circuit structure 304. The second position P2 is farther from the circuit structure 304 than the first position P1. The first position P1 has a first width W1, the second position P2 has a second width W2, and the first width W1 of the first position P1 is greater than the second width W2 of the second position P2. In accordance with some embodiments, the ratio of the first width W1 to the second width W2 may be between 0.8 and 2.5, or between 1.2 and 2.

Furthermore, as shown in FIG. 5, in accordance with some embodiments, the electronic device 10 may include a conductive bump 306B-2. The conductive bump 306B-2 may be disposed on the encapsulation layer 300 and opposite to the circuit structure 304. The conductive bump 306B-2 may be in contact with a third position P3 of the through hole 300v-1, and the third position P3 has a third width W3. The third width W3 may be smaller than the first width W1, and the third width W3 may be smaller than the second width W2. In accordance with some embodiments, the ratio of the first width W1 to the third width W3 may be between 0.8 and 2.5, or between 1.2 and 2. In accordance with some embodiments, the ratio of the second width W2 to the third width W3 may be between 1.1 and 2.3, or between 1.2 and 1.8. In addition, in accordance with some embodiments, the electronic device 10 may include a conductive bump 306B-1, and the conductive bump 306B-1 may be connected to the heat dissipation film 104 through the opening 300v-2 of the encapsulation layer 300.

As described above, in accordance with some embodiments, the chip unit 10U may include a chip 200u and a buffer layer 208 disposed on the chip 200u, and the circuit structure 304 may be electrically connected to the chip 200u through the opening 208v of the buffer layer 208. In accordance with some embodiments, the top portion (not labeled) or the bottom portion (not labeled) of the chip 200u may have a recess RS. In addition, in accordance with some embodiments, the chip unit 10U may further include a wall structure 204w, which may be disposed between the chip 200u and the buffer layer 208 and adjacent to the side surface 200s of the chip 200u.

In accordance with some embodiments, the heat dissipation film 104 may have a protruding portion 104R that protrudes in a direction away from the chip 200u. In accordance with some embodiments, the included angle θ1 (not labeled, please refer to FIG. 3A) between the extending direction E104 of the protruding portion 104R (not labeled, please refer to FIG. 3A) and the first side S1 of the chip unit 10U may be between 45 degrees and 135 degrees. According to above design, the adhesion between the heat dissipation film 104 and other layers will be improved. In accordance with some embodiments, the heat dissipation film 104 may have a first thickness T104 (not labeled, please refer to FIG. 3A), the protruding portion 104R may have a second thickness TR (not labeled, please refer to FIG. 3A), and the first thickness T104 and the second thickness TR conform to the following relationship: 1.2× the first thickness T104≤the second thickness TR≤5× the first thickness T104. That is, the second thickness TR of the protruding portion 104R may be greater than or equal to 1.2 times the first thickness T104 of the heat dissipation film 104, and the second thickness TR of the protruding portion 104R is less than or equal to 5 times the first thickness T104 of the heat dissipation film 104.

In addition, the electronic device 10 may be connected to an external electronic component 500 through the bonding element 308 and the connection pad 502. One end of the connection pad 502 may be electrically connected to the bonding element 308 of the electronic device 10, and the other end of the connection pad 502 may be electrically connected to the external electronic component 500. In accordance with some embodiments, the external electronic component 500 may include, for example, a printed circuit board (PCB), an IC carrier, or another suitable component, but the present disclosure is not limited thereto.

In accordance with some embodiments, the material of the connection pad 502 may include tin, silver, lead-free tin, copper, nickel, gold, another suitable material or a combination thereof, but it is not limited thereto. In accordance with some embodiments, the connection pad 502 may be bonded to the bonding element 308 through a reflow process, a fusion bonding process, a hybrid bonding process, a metal-to-metal bonding process, another suitable method, or a combination thereof.

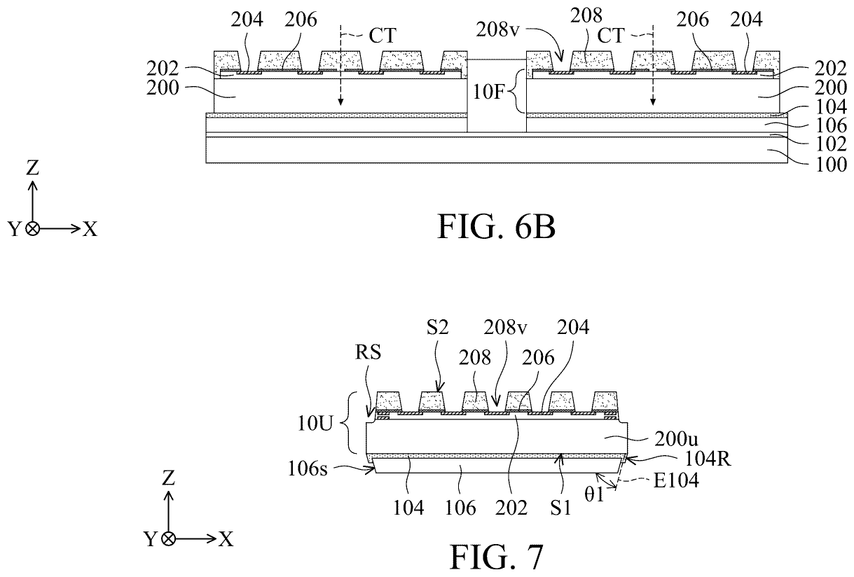

Please refer to FIG. 6A and FIG. 6B, which are cross-sectional diagrams of an electronic device in different stages of the manufacturing process in accordance with some other embodiments of the present disclosure. The steps shown in FIG. 6A and FIG. 6B are similar to the aforementioned FIG. 2B and FIG. 2E respectively. The main difference between them is that the embodiments shown in FIG. 6A and FIG. 6B further include a step of forming an anti-crack film 106. It should be understood that components or elements that are the same as or similar to those mentioned above will be denoted by the same or similar numerals, and their materials and functions are the same or similar to those described above, and thus will not be repeated in the following description.

Please refer to FIG. 6A. In accordance with some embodiments, after the carrier substrate 100 is provided, the anti-crack film 106 is first formed on the carrier substrate 100, and then the heat dissipation film 104 is formed on the carrier substrate 100. Then, the wafer unit 10F may be formed on the heat dissipation film 104, and a surface treatment CL may be performed on the top surface of the wafer unit 10F. For example, the surface treatment CL may be performed on the exposed top surfaces of the conductive pad 204 and the passivation layer 206.

In accordance with some embodiments, the anti-crack film 106 may include a polymer insulating material, for example, may include ABF build-up film (Ajinomoto Build-up Film), polybenzoxazole (PBO), polyimide, photosensitive polyimide (PSPI), benzene cyclobutene (BCB), epoxy resin, another suitable material or a combination thereof, but it is not limited thereto. In accordance with some other embodiments, the anti-crack film 106 may include adhesive material, such as optical clear adhesive (OCA), optical clear resin (OCR), pressure sensitive adhesive (PSA), acrylic glue, acrylic resin, another suitable material, or a combination thereof, but it is not limited thereto. In accordance with some embodiments, the anti-crack film 106 may be formed on the carrier substrate 100 through a lamination process, a coating process, a spin coating process, a chemical vapor deposition process, another suitable method, or a combination thereof. In accordance with some other embodiments, the anti-crack film 106 may include a heat dissipation material, for example, the material with a thermal conductivity coefficient greater than or equal to 100 W/m·K. In accordance with some other embodiments, the anti-crack film 106 and the heat dissipation film 104 may include copper or another metal, such as metallic copper foil or copper sheets, or the anti-crack film 106 and the heat dissipation film 104 may be connected to each other or integrally formed. In accordance with some embodiments, the difference between the thermal expansion coefficient of the anti-cracking film 106 and the thermal expansion coefficient of the external electronic component 500 may be less than the difference between the thermal expansion coefficient of the buffer layer 208 and the thermal expansion coefficient of the external electronic component 500. For example, when the external electronic component 500 is a multi-layer stack, the thermal expansion coefficient of the layer closest to the chip 200u may be compared with the thermal expansion coefficient of the anti-cracking film 106. That is, when the thermal expansion coefficient of the anti-cracking film 106 is close to the thermal expansion coefficient of the external electronic component 500, the bonding strength between the electronic device and the external electronic component 500 can be improved, but it is not limited thereto.

Referring to FIG. 6B, the buffer material 208m then may be formed on the wafer unit 10F, and a patterning process may be performed on the buffer material 208m to form the buffer layer 208, but it is not limited thereto. In some embodiments, the patterning process may be performed after providing the encapsulation layer 300 to surround the chip unit 10U. After the buffer layer 208 is formed, a cutting process CT may be performed on the wafer 200, the interposer 202 and the buffer layer 208 to form the chip unit 10U. Furthermore, the cutting process CT may also cut the release layer 102, the anti-cracking film 106 and the heat dissipation film 104 together.

Next, please refer to FIG. 7, which is a cross-sectional diagram of the electronic device obtained following the steps shown in FIG. 6B. Specifically, FIG. 7 shows the partial structure of the electronic device obtained after performing the cutting process CT on the wafer unit 10F and removing the release layer 102 and the carrier substrate 100 (for clarity of explanation, only the area corresponding to a single wafer is shown).

As shown in FIG. 7, the chip unit 10U may include the chip 200u and the interposer 202, the conductive pad 204, the passivation layer 206 and the buffer layer 208 disposed on the chip 200u. The chip unit 10U may have the first side S1 and the second side S2 opposite to the first side S1. The first side S1 may be a side close to the chip 200u, and the second side S2 may be a side close to the buffer layer 208. Furthermore, the heat dissipation film 104 may be disposed on the first side S1 of the chip unit 10U. The anti-crack film 106 and the chip unit 10U may be disposed on both sides of the heat dissipation film 104.

As described above, the heat dissipation film 104 may have the protruding portion 104R that protrudes in a direction away from the chip 200u. Similarly, in accordance with some embodiments, the included angle θ1 between the extending direction E104 of the protruding portion 104R and the first side S1 of the chip unit 10U may be between 45 degrees and 135 degrees. Furthermore, the protruding portion 104R may be partially disposed on the side surface 106s of the anti-crack film 106.

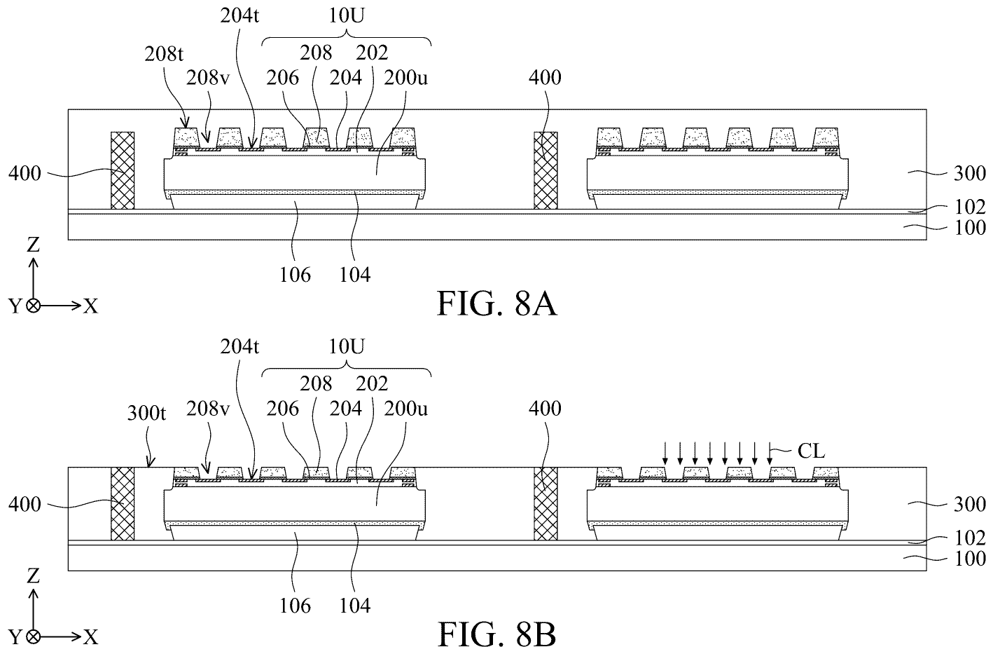

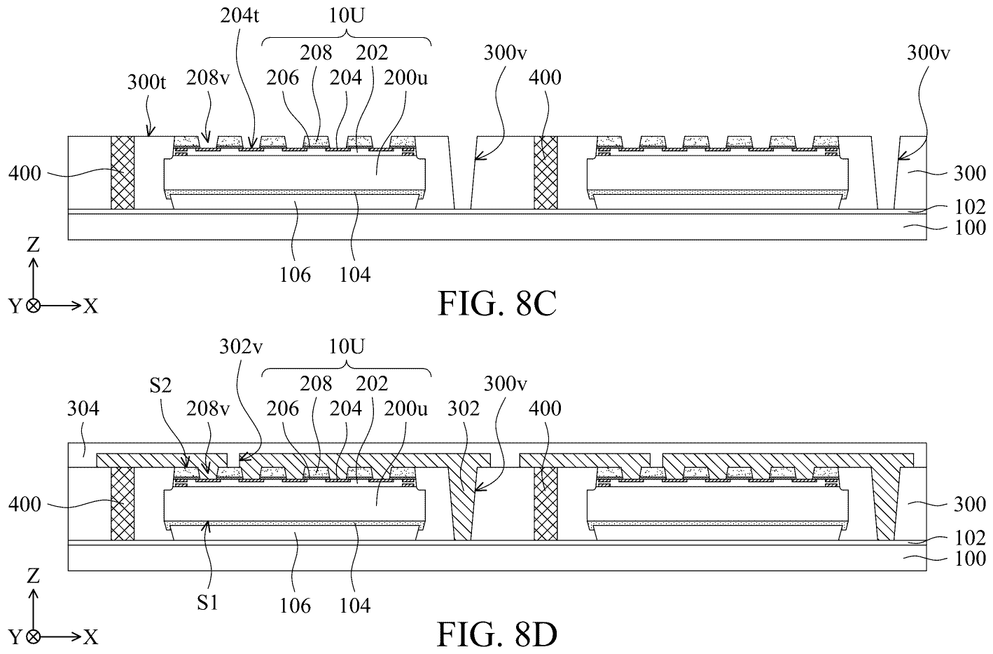

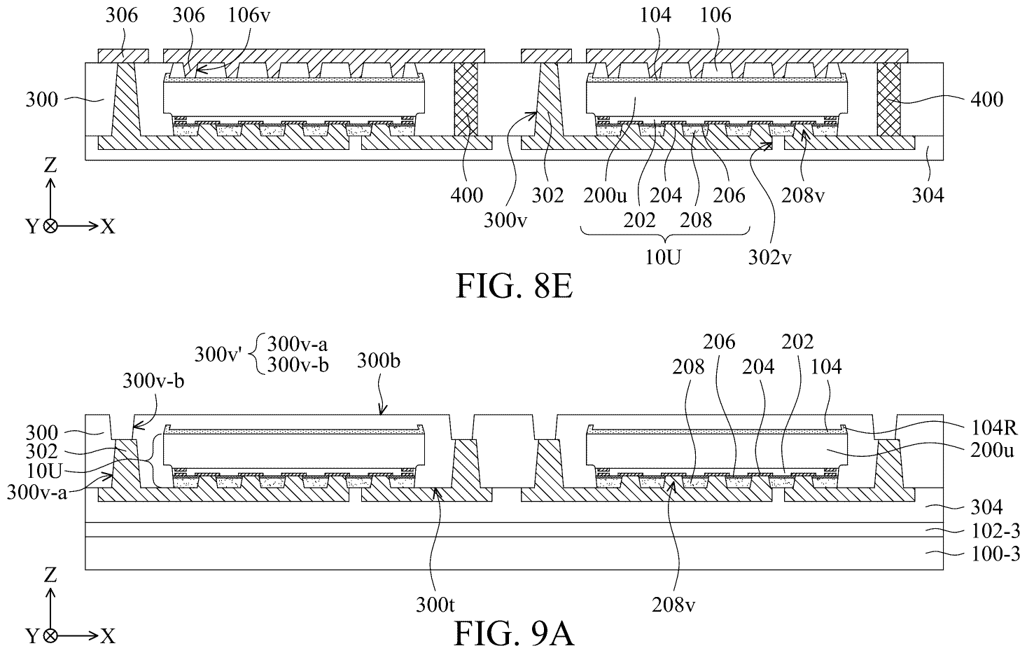

Please refer to FIGS. 8A to 8E, which are cross-sectional diagrams of an electronic device in different stages of the manufacturing process in accordance with some other embodiments of the present disclosure. Specifically, FIGS. 8A to 8E show partial cross-sectional diagrams of an electronic device obtained by continuing the packaging process with the structure shown in FIG. 7. It should be understood that components or elements that are the same as or similar to those mentioned above will be denoted by the same or similar numerals, and their materials and functions are the same or similar to those described above, and thus will not be repeated in the following description.

Please refer to FIG. 8A. First, the structure including the chip unit 10U, the heat dissipation film 104 and the anti-crack film 106 shown in FIG. 7 may be disposed on the carrier substrate 100. Moreover, the release layer 102 may be formed on the carrier substrate 100 first, so that the release layer 102 is located between the carrier substrate 100 and the chip unit 10U. The release layer 102 may be removed together with the carrier substrate 100 from the subsequently formed overlying structure.

Next, an encapsulation layer 300 may be formed to surround the chip unit 10U, the heat dissipation film 104 and the anti-crack film 106. In accordance with some embodiments, the encapsulation layer 300 may be formed over the carrier substrate 100 and the release layer 102, and cover the chip unit 10U, the heat dissipation film 104 and the anti-crack film 106. The encapsulation layer 300 may be in contact with the surfaces of the chip unit 10U, the heat dissipation film 104 and the anti-cracking film 106.

In addition, a conductive element 400 may be further formed above the carrier substrate 100 and the release layer 102, and the conductive element 400 may be disposed around the chip unit 10U. In accordance with some embodiments, the conductive element 400 can be used as an alignment mark or can provide sufficient buffering stress during the packaging process to improve the stability of the structure.

In accordance with some embodiments, the material of the conductive element 400 may include a metal or doped semiconductor material, such as silicon (Si), germanium (Ge), another suitable material, or a combination thereof, but it is not limited thereto. In accordance with some embodiments, the conductive element 400 may be formed by a chemical vapor deposition process, an atomic layer deposition process, a vapor epitaxy process, a molecular beam epitaxy process, another suitable method, or a combination thereof, but it is not limited thereto.

Referring to FIG. 8B, a planarization process may be performed on the first surface 300t of the encapsulation layer 300 (for example, the top surface of the encapsulation layer 300 in FIG. 8A) to expose the conductive element 400 and the buffer layer 208. As shown in FIG. 8B, after the planarization process is performed, the first surface 300t of the encapsulation layer 300 and the top surfaces (not labeled) of the conductive element 400 and the buffer layer 208 may be substantially aligned or coplanar. In accordance with some embodiments, the planarization process may include a grinding process, a chemical-mechanical polish (CMP) process, another suitable planarization process, or a combination thereof.

A surface treatment CL may then be performed on the top surface of the planarized structure, such as the top surfaces of the encapsulation layer 300 and the exposed conductive element 400 and buffer layer 208. In accordance with some embodiments, the surface treatment CL may include a surface cleaning process, such as a plasma surface cleaning process, but it is not limited thereto.

Please refer to FIG. 8C, and then a through hole 300v may be formed in the encapsulation layer 300. Specifically, a patterning process may be performed to remove a portion of the encapsulation layer 300 from the first surface 300t of the encapsulation layer 300 to form the through hole 300v, and the through hole 300v may expose a portion of the surface of the release layer 102. In accordance with some embodiments, the through hole 300v and the conductive element 400 may be disposed on both sides of the chip unit 10U, but it is not limited thereto. Furthermore, the encapsulation layer 300 disposed in the opening 208v may be removed to expose a portion of the surface of the conductive pad 204.

In accordance with some embodiments, a portion of the encapsulation layer 300 may be removed through one or more photolithography processes and/or etching processes to form the through hole 300v and the opening 208v in the encapsulation layer 300.

Referring to FIG. 8D, a conductive layer 302 then may be formed in the through hole 300v. In addition, the conductive layer 302 also may be formed on the conductive element 400, the encapsulation layer 300 and the buffer layer 208, and fill in the opening 208v of the buffer layer 208. The conductive layer 302 may be electrically connected to the chip unit 10U through the opening 208v, and the conductive layer 302 also may be electrically connected to the conductive element 400.

Continuing to refer to FIG. 8D, a circuit structure 304 then may be formed on the second side S2 of the chip unit 10U, and the through hole 300v may be electrically connected to the chip unit 10U through the circuit structure 304. The circuit structure 304 may be formed over conductive layer 302. Furthermore, in accordance with some embodiments, the circuit structure 304 may be electrically connected to the chip 200u through the opening 208v of the buffer layer 208.

Referring to FIG. 8E, the carrier substrate 100 and the release layer 102 then may be removed, and the structure originally disposed on the carrier substrate 100 may be inverted. After being inverted the chip unit 10U may be disposed above and the circuit structure 304 may be disposed below. Then, a through hole 106v may be formed in the anti-crack film 106, and the through hole 106v may penetrate the anti-crack film 106 and expose a portion of the surface of the heat dissipation film 104. Furthermore, a conductive layer 306 may be formed in the through hole 106v. In addition, the conductive layer 306 also may be formed on the encapsulation layer 300 and in contact with the conductive layer 302 and the conductive element 400 disposed in the through holes 300v, so that the conductive layer 306 is electrically connected to the conductive layer 302 and the conductive element 400, and then is electrically connected to the chip unit 10U.

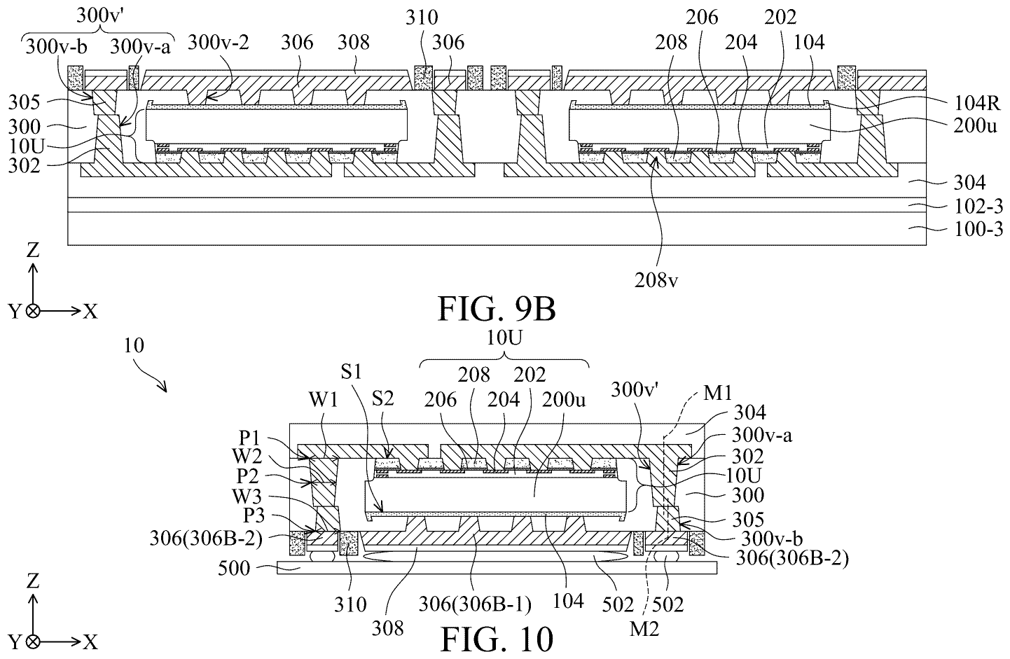

Please refer to FIG. 9A and FIG. 9B, which are cross-sectional diagrams of an electronic device in different stages of the manufacturing process in accordance with some other embodiments of the present disclosure. Specifically, FIG. 9A and FIG. 9B show partial cross-sectional diagrams of the electronic device obtained by following the steps shown in FIG. 4C in accordance with some other embodiments of the present disclosure. It should be understood that components or elements that are the same as or similar to those mentioned above will be denoted by the same or similar numerals, and their materials and functions are the same or similar to those described above, and thus will not be repeated in the following description.

Referring to FIG. 9A, the second carrier substrate 100-2 and the second release layer 102-2 may be removed, and the structure as shown in FIG. 4C originally disposed on the second carrier substrate 100-2 may be inverted and disposed on a third carrier substrate 100-3. Next, a portion of the encapsulation layer 300 may be removed from the second surface 300b of the encapsulation layer 300 to expose the conductive layer 302 disposed in a through hole 300v-a (similar to the through hole 300v-1 in FIG. 4C).

As described above, in this embodiment, the step of forming a through hole penetrating the encapsulation layer 300 includes performing a first patterning process and a second patterning process. The first patterning process includes removing a portion of the encapsulation layer 300 from the first surface 300t of the encapsulation layer 300, and the second patterning process includes removing another portion of the encapsulation layer 300 from the second surface 300b of the encapsulation layer 300. In detail, removing a portion of the encapsulation layer 300 from the first surface 300t of the encapsulation layer 300 may form a through hole 300v-a, and removing a portion of the encapsulation layer 300 from the second surface 300b of the encapsulation layer 300 may form a through hole 300v-b. The through hole 300v-a and the through hole 300v-b may be combined to form a through hole 300v′, and the through hole 300v′ may penetrate the encapsulation layer 300.

Referring to FIG. 9B, a conductive layer 305 may be formed in the through hole 300v-b. The conductive layer 305 may be in contact with the conductive layer 302. The material of the conductive layer 305 may be the same or similar to that of the conductive layer 302. Moreover, similar to the steps shown in FIG. 4E, an insulating layer 310 then may be formed on the encapsulation layer 300, an opening 300v-2 may be formed in the encapsulation layer 300, and a conductive layer 306 may be formed in the opening 300v-2. In addition, the conductive layer 306 also may be formed on the encapsulation layer 300 and in contact with the conductive layer 302 and the conductive layer 305 disposed in the through hole 300v′ so that the conductive layer 306 is electrically connected to the conductive layer 302 and the conductive layer 305, and then is electrically connected to the chip unit 10U. Next, a bonding element 308 may be formed on the conductive layer 306.

Please refer to FIG. 10, which is a cross-sectional diagram of an electronic device 10′ in accordance with some embodiments of the present disclosure. Specifically, FIG. 10 shows a partial cross-sectional diagram of a structure obtained by further bonding the electronic device shown in FIG. 9B to an external electronic component 500.

As shown in FIG. 10, in accordance with some embodiments, the aforementioned third carrier substrate 100-3 and third release layer 102-3 may be removed, and the structure originally disposed on the third carrier substrate 100-3 may be inverted and bonded to the external electronic components 500.

Furthermore, the electronic device 10 formed by the aforementioned manufacturing method is substantially similar to the embodiment shown in FIG. 5. Similarly, in the embodiment shown in FIG. 10, the through hole 300v′ has a first position P1 and a second position P2. The first position P1 is connected to the circuit structure 304. The second position P2 is farther away from the circuit structure 304 than the first position P1. The first position P1 has a first width W1, the second position P2 has a second width W2, and the first width W1 of the first position P1 is greater than the second width W2 of the second position P2.

As shown in FIG. 10, in accordance with some embodiments, the electronic device 10 may include a conductive bump 306B-2 disposed on the encapsulation layer 300 and opposite to the circuit structure 304. The conductive bump 306B-2 may be in contact with a third position P3 of the through hole 300v′, and the third position P3 has a third width W3. Differently, in this embodiment, the third width W3 is greater than the second width W2. In accordance with some embodiments, the ratio of the first width W1 to the third width W3 may be between 0.7 and 2, or between 0.9 and 1.8. In accordance with some embodiments, the ratio of the second width W2 to the third width W3 may be between 1.1 and 2.3, or between 1.2 and 1.8. Through the above design, the electrical performance or the heat dissipation performance of the electronic device can be improved. In accordance with some embodiments, the electronic device may include another through hole, and this through hole may have a ground signal, but it is not limited thereto.

In addition, in this embodiment, a center line M1 of the conductive layer 302 disposed in the through hole 300v-a and a center line M2 of the conductive layer 305 disposed in the through hole 300v-b may be offset or misaligned. In other words, the through hole 300v-a and the through hole 300v-b may be arranged in a staggered manner. In accordance with some embodiments, the distance (not labeled) between the center line M1 of the conductive layer 302 in the through hole 300v-a and the center line M2 of the conductive layer 305 disposed in the through hole 300v-b may be less than 5 μm, for example, less than 4 μm, 3 μm, 2 μm or 1 μm, but it is not limited thereto.

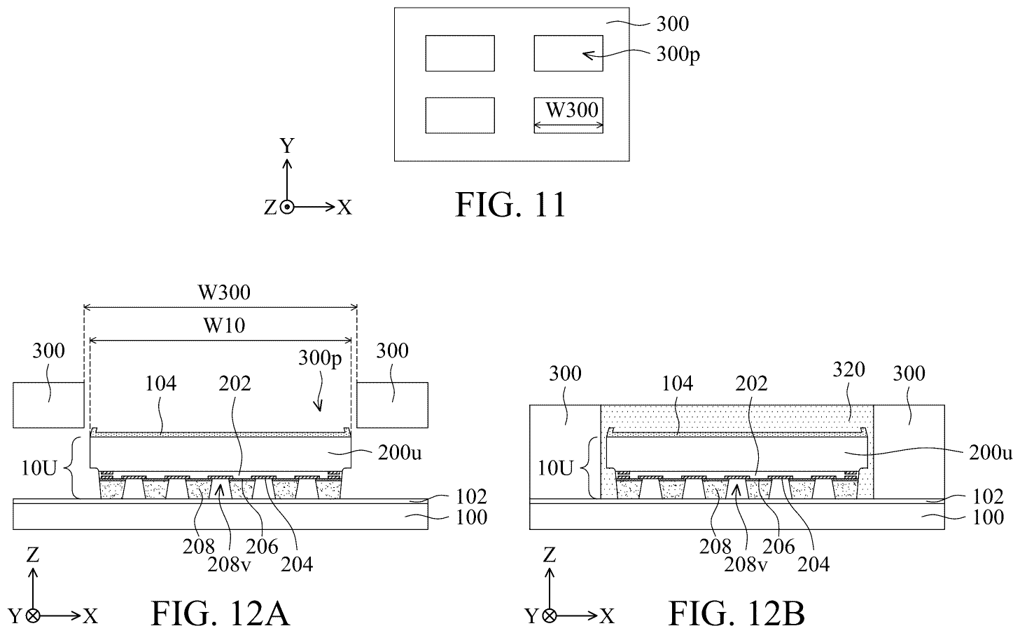

Please refer to FIG. 11, FIG. 12A and FIG. 12B. FIG. 11 is a top-view diagram of an encapsulation layer 300 of an electronic device in accordance with some embodiments of the present disclosure. FIG. 12A and FIG. 12B are cross-sectional diagrams of an electronic device manufactured using the aforementioned encapsulation layer 300 in accordance with some embodiments of the present disclosure.

As shown in FIG. 11, in accordance with some embodiments, the encapsulation layer 300 may be a mold having openings 300p. The opening 300p may have a width W300, and the opening 300p may be adjusted corresponding to the size of the wafer unit or the chip unit.

Referring to FIG. 12A and FIG. 12B, in accordance with some embodiments, the encapsulation layer 300 may be disposed on the carrier substrate 100 and the release layer 102, and the opening 300p may be disposed corresponding to the structure of electronic device in the manufacturing process (for example, the chip unit 10U shown in FIG. 3A). The width W300 of the opening 300p may be larger than the width W10 of the structure of electronic device. Moreover, in accordance with some embodiments, after the encapsulation layer 300 is disposed on the carrier substrate 100, a filler 320 may be further formed in the opening 300p. The opening 300p may be disposed between the encapsulation layer 300 and the chip unit 10U, and the filler 320 may surround the chip unit 10U and the heat dissipation film 104.

In accordance with some embodiments, the material of the filler 320 may include a polymer insulating material, such as ABF build-up film (Ajinomoto Build-up Film), polybenzoxazole (PBO), polyimide, photosensitive polyimide (PSPI), benzene cyclobutene (BCB), epoxy resin, another suitable material or a combination thereof, but it is not limited thereto. In accordance with some other embodiments, the filler 320 may include adhesive material, such as optical clear adhesive (OCA), optical clear resin (OCR), pressure sensitive adhesive (PSA), acrylic adhesive, acrylic resin, another suitable material, another suitable transparent material, or a combination thereof, but it is not limited thereto. In accordance with some embodiments, the material of the filler 320 may be the same as or different from that of the encapsulation layer 300.

In particular, the aforementioned encapsulation layer 300 in the form of a mold can reduce the use of patterning processes or planarization processes, thereby reducing the risk of damage or cracking of the structure during the manufacturing process.

To summarize the above, in accordance with the embodiments of the present disclosure, the electronic device provided includes a packaging structure design with a heat dissipation film and a through mold via (TMV), which can reduce and thin the packaging structure and improve the heat dissipation effect, high voltage resistance and current resistance of the electronic device. Therefore, the overall performance and reliability of the electronic device can be improved.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a wafer unit having a first side and a second side opposite to the first side;
a heat dissipation film disposed on the first side of the chip unit;
an encapsulation layer surrounding the chip unit and the heat dissipation film;
a through hole penetrating the encapsulation layer, wherein the through hole has a first position and a second position; and
a circuit structure disposed on the second side of the chip unit, wherein the through hole is electrically connected to the chip unit through the circuit structure,
wherein the first position is connected to the circuit structure, the second position is farther away from the circuit structure than the first position, the first position has a first width, the second position has a second width, and the first width is greater than the second width.

2. The electronic device as claimed in claim 1, wherein the chip unit comprises:
a chip; and
a buffer layer disposed on the chip.

3. The electronic device as claimed in claim 2, wherein the circuit structure is electrically connected to the chip through an opening of the buffer layer.

4. The electronic device as claimed in claim 2, wherein the heat dissipation film has a protruding portion, and the protruding portion protrudes in a direction away from the chip.

5. The electronic device as claimed in claim 4, wherein an included angle between an extending direction of the protruding portion and the first side is between 45 degrees and 135 degrees.

6. The electronic device as claimed in claim 1, further comprising:
a first conductive bump disposed on the encapsulation layer and opposite to the circuit structure, wherein the first conductive bump is in contact with a third position of the through hole, the third position has a third width, the third width is smaller than the first width, and the third width is smaller than the second width.

7. The electronic device as claimed in claim 1, further comprising:
a first conductive bump disposed on the encapsulation layer and opposite to the circuit structure, wherein the first conductive bump is in contact with a third position of the through hole, the third position has a third width, and the third width is greater than the second width.

8. The electronic device as claimed in claim 7, further comprising:
a second conductive bump connected to the heat dissipation film through an opening in the encapsulation layer.

9. The electronic device as claimed in claim 2, wherein a top portion or a bottom portion of the chip has at least one recess.

10. The electronic device as claimed in claim 2, wherein a side surface of the chip has at least one inclined profile.

11. The electronic device as claimed in claim 4, wherein the heat dissipation film has a first thickness, the protruding portion has a second thickness, and the first thickness and the second thickness conform to the following relationship:
1.2×the first thickness≤the second thickness≤5×the first thickness.

12. The electronic device as claimed in claim 1, further comprising:
an anti-crack film, wherein the anti-crack film and the chip unit are disposed on both sides of the heat dissipation film.

13. The electronic device as claimed in claim 1, further comprising:
a filler disposed between the encapsulation layer and the chip unit and surrounding the chip unit and the heat dissipation film.

14. The electronic device as claimed in claim 2, wherein the chip unit further comprises:
a wall structure disposed between the chip and the buffer layer and adjacent to a side surface of the wafer.

15. A method of manufacturing an electronic device, comprising:
providing a carrier substrate;
providing a heat dissipation film on the carrier substrate;
providing a wafer on the heat dissipation film;
performing a cutting process on the wafer to form a chip unit, wherein the chip unit has a first side and a second side opposite to the first side;
providing an encapsulation layer surrounding the chip unit and the heat dissipation film;
forming a through hole penetrating the encapsulation layer, wherein the through hole has a first position and a second position; and
providing a circuit structure on the second side of the chip unit, wherein the through hole is electrically connected to the chip unit through the circuit structure,
wherein the first position is connected to the circuit structure, the second position is farther away from the circuit structure than the first position, the first position has a first width, the second position has a second width, and the first width is greater than the second width.

16. The method of manufacturing an electronic device as claimed in claim 15, wherein before performing the cutting process on the wafer, the method further comprises:
forming a buffer material on the wafer; and
performing a patterning process on the buffer material to form a buffer layer.

17. The method of manufacturing an electronic device as claimed in claim 16, wherein the step of performing the cutting process on the wafer comprises:
cutting along a dicing lane passing through the buffer layer and the wafer to form the chip unit, wherein the chip unit comprises a chip and the buffer layer disposed on the chip.

18. The method of manufacturing an electronic device as claimed in claim 15, wherein the cutting process comprises a laser cutting process, a knife cutting process or a combination thereof.

19. The method of manufacturing an electronic device as claimed in claim 17, wherein after performing the cutting process on the wafer, a top portion or a bottom portion of the chip has at least one recess, or the chip has at least one inclined profile.

20. The method of manufacturing an electronic device as claimed in claim 15, wherein the encapsulation layer has a first surface and a second surface opposite to the first surface, and forming the through hole comprises:
performing a first patterning process to remove a portion of the encapsulation layer from the first surface of the encapsulation layer; and
performing a second patterning process to remove another portion of the encapsulation layer from the second surface of the encapsulation layer.
